(19) United States
(12) Patent Application Publication
(10) Pub. No.: US 2023/0215605 A1
(43) Pub. Date: Jul. 6, 2023

(54) METHOD AND APPARATUS FOR FORMING ELECTRODE BY USING INKJET PRINTING

(71) Applicant: GOSANTECH CO., LTD., Cheonan-si (KR)

(72) Inventor: Dongkyun SHIN, Sejong-si (KR)

(73) Assignee: GOSANTECH CO., LTD., Cheonan-si (KR)

(21) Appl. No.: 17/989,240

(22) Filed: Nov. 17, 2022

(30) Foreign Application Priority Data
Dec. 30, 2021 (KR) 10-2021-0192050

(51) Int. Cl. H01B 13/00

(52) U.S. Cl. CPC H01B 13/0036

(57) ABSTRACT

Proposed is a method of forming an electrode on a surface of an object by using inkjet printing, the method including forming a buffer on an outer edge of an electrode formation position, and forming the electrode by filling electrode ink inside the buffer, wherein the buffer formation is performed by stacking buffer layers formed by inkjet printing of buffer ink, and hydrophilicity of a surface of each of the buffer layers is lower than hydrophilicity of the object surface. According to an electrode forming apparatus, the buffer constituting the outer edge of the electrode is formed high and the electrode ink is filled inside the buffer to form the electrode, thereby enabling the formation of the electrode having an increased sectional area.

### CROSS REFERENCE TO RELATED APPLICATION

The present application claims priority to Korean Patent Application No. 10-2021-0192050, filed Dec. 30, 2021, the entire contents of which are incorporated herein for all purposes by this reference.

### BACKGROUND OF THE INVENTION

### Field of the Invention

The present disclosure relates generally to method and apparatus for forming an electrode of an electronic device. More particularly, the present disclosure relates to method and apparatus for forming an electrode of an electronic device by using inkjet printing.

### Description of the Related Art

Generally, an electronic device refers to an electronic component using conduction of electrons moving in a solid, and electrodes for moving electricity are formed in the electronic device.

Various types of electrodes are formed according to the characteristics of various electronic devices, and as the miniaturization and precision of an electronic device progresses, the size of an electrode decreases and the shape of the electrode is required to be more precise.

As a method of forming a small and precise pattern, an inkjet printing technology may be applied. The inkjet method of ejecting liquid ink in the form of a droplet on the surface of a medium according to a shape signal is used not only as printing for creating documents or flyers, but also in solution processes in semiconductor or display fields. Particularly, the scope of application of inkjet printing, by which a pattern of a complex shape can be formed on a substrate or ink can be precisely ejected only on a specific location, is expanding.

In order to eject the correct amount of ink in an inkjet printing process, ink in an inkjet head ready for ejection is required to maintain a meniscus state, which is a curved state in which the ink is recessed inward by capillary action based on a nozzle inlet. To this end, the position of the ink storage part is placed higher than the inkjet head, and instead, by generating negative pressure inside an ink storage tank, ink is prevented from flowing down from the inkjet head to maintain the meniscus state. However, since there is difference in the viscosity of ink, it is not enough to simply generate negative pressure inside the ink storage tank.

Specifically, the process of ejecting ink in the form of a droplet is greatly affected by surface tension and viscosity of the ink. Viscosity is important in inkjet printing since the viscosity is related to how easily ink flows through a head channel and is compressed in a nozzle, and surface tension is important in inkjet printing since the surface tension is related to how well ink can form an optimally rounded droplet. In general, to facilitate inkjet printing, it is advantageous that ink has low viscosity, but the low viscosity of the ink causes printed ink to spread easily. Accordingly, the printed result has low height from the surface of a printed object and has often thin thickness (hereinafter, height between the surface of an object and the upper surface of an electrode is referred to as “thickness” of the electrode). However, as the electrode is thin in thickness and decreases in a sectional area, the internal resistance of the electrode increases. Particularly, in the case of an electrode of an ultra-precision electronic device, the line width of the electrode is very small, and thus when the height of the electrode is low, resistance of the electrode may be a problem, which leads to limitation in materials constituting the electrode and increase in manufacturing costs.

Accordingly, an attempt to increase the height of an electrode by repeating inkjet printing at the same position has been made as illustrated in FIG. 10, but as long as the characteristics of ink is not changed, there is limitation in increasing the height of an electrode by the repeated inkjet printing, and ink stacked on an upper side flows down and the line width of the electrode is increased more than a target value, thereby resulting in a defect.

Alternatively, a technique for changing the contact angle of ink by changing the surface characteristics of an object on which the ink is printed while maintaining the viscosity of the ink has been studied (Korean Patent Application Publication No. 10-2005-0074195). However, according to material characteristics of an object, the surface treatment of the object may be impossible and there may be the risk of damage to other parts in the process of the surface treatment of the object, and accordingly, the above-described technique has very limited application and is not actually used.

### DOCUMENT OF RELATED ART

(Patent Document 1) Korean Patent Application Publication No. 10-2005-0074195

### SUMMARY OF THE INVENTION

Accordingly, the present disclosure has been made keeping in mind the above problems occurring in the related art, and the present disclosure is intended to propose method and apparatus for forming an electrode with high height by using inkjet printing.

In order to achieve the above objective, according to one aspect of the present disclosure, there is provided a method of forming an electrode on a surface of an object by using inkjet printing, the method including: forming a buffer on an outer edge of an electrode formation position; and forming the electrode by filling electrode ink inside the buffer, wherein the buffer formation is performed in such a manner that a process of forming a buffer layer by inkjet printing of buffer ink is repeated to stack buffer layers, and hydrophilicity of a surface of the buffer layer is lower than hydrophilicity of the object surface.

The buffer formation may be performed in such a manner that a process of forming a buffer layer by inkjet printing of each of at least two types of buffer inks having different ingredients is repeated to stack buffer layers.

The buffer formation may include a process of performing surface treatment of the buffer layer, wherein the surface treatment may allow the hydrophilicity of the buffer layer surface to be lower than the hydrophilicity of the object surface.

The buffer formation may be performed by stacking the buffer layer at least two times to form a plurality of buffer layers, wherein a surface of at least one of the plurality of buffer layers may be treated to have hydrophilicity lower than the hydrophilicity of the object surface.

According to the present disclosure, there is provided an apparatus for forming an electrode on a surface of an object by using inkjet printing, the apparatus including: a buffer ink discharge module for inkjet printing of buffer ink which forms a buffer layer whose surface has hydrophilicity lower than hydrophilicity of the object surface; an electrode ink discharge module for inkjet printing of electrode ink inside a buffer whose buffer layers are stacked; a dryer for drying inkjet-printed ink; a stage for mounting the object on which the electrode is formed; and a transportation means which moves a position of the object, which is installed on the stage, relative to the buffer ink discharge module, the electrode ink discharge module, and the dryer.

The buffer ink discharge module may include at least two buffer ink discharge modules to eject buffer inks different from each other.

The apparatus may further include: a surface treatment device which treats a surface of a buffer layer in which buffer ink is dried such that hydrophilicity of the surface of the buffer layer is lower than the hydrophilicity of the object surface.

According to the electrode forming apparatus having the above-described configuration, a buffer constituting the outer edge of an electrode is formed high and electrode ink is filled inside the buffer to form the electrode, thereby increasing the thickness of the electrode and enabling the formation of the electrode having an increased sectional area.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a sectional view illustrating a process of forming a buffer in the method for forming an electrode of an electronic device by using inkjet printing according to a first embodiment of the present disclosure;

FIG. 2 is a view illustrating a section of an electrode formed in the method for forming an electrode of an electronic device by using inkjet printing according to the first embodiment of the present disclosure;

FIGS. 3A and 3B are views illustrating the structure of the electrode forming apparatus for forming an electrode in the first embodiment according to the method for forming an electrode of an electronic device by using inkjet printing according to the present disclosure;

FIG. 4 is a sectional view illustrating the process of forming a buffer in the method for forming an electrode of an electronic device by using inkjet printing according to a second embodiment of the present disclosure;

FIGS. 5A and 5B are views illustrating the structure of the electrode forming apparatus for forming an electrode in the second embodiment according to the method for forming an electrode of an electronic device by using inkjet printing according to the present disclosure;

FIG. 6 is a sectional view illustrating the method for forming an electrode of an electronic device by using inkjet printing according to a third embodiment of the present disclosure;

FIGS. 7A and 7B are views illustrating the structure of the electrode forming apparatus for forming an electrode in the third embodiment according to the method for forming an electrode of an electronic device by using inkjet printing according to the present disclosure;

FIG. 8 is a sectional view illustrating the method for forming an electrode of an electronic device by using inkjet printing according to a fourth embodiment of the present disclosure;

FIGS. 9A and 9B are views illustrating the structure of the electrode forming apparatus for forming an electrode in the fourth embodiment according to the method for forming an electrode of an electronic device by using inkjet printing according to the present disclosure; and

FIG. 10 is a sectional view illustrating a case in which inkjet printing of a conventional technology is repeatedly performed.

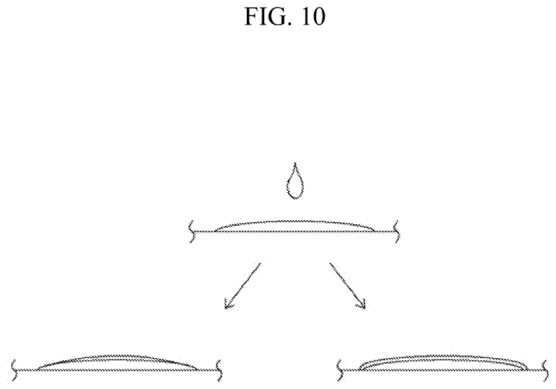

### DETAILED DESCRIPTION OF THE INVENTION

Embodiments according to the present disclosure will be described in detail with reference to the accompanying drawings.

However, the embodiments of the present disclosure may be modified in various other forms, and the scope of the present disclosure is not limited only to the embodiments described below. The shapes and sizes of elements in the drawings may be exaggerated for clearer description, and elements indicated by the same reference numerals in the drawings are the same elements.

In addition, throughout the specification, when a part is “connected” with another part, it includes not only the case of the part being “directly connected” with the another part but also the case of the part being “electrically connected” with the another part with still another element interposed therebetween. In addition, when a part “includes” or “is provided with” a certain component, this means that other components may be further included or provided without excluding the other components unless otherwise stated.

In addition, terms such as “first” and “second” are for distinguishing one component from another component, and the scope of the claims should not be limited by these terms. For example, a first component may be termed a second component, and similarly, a second component may also be termed a first component.

Inventors of an electrode forming apparatus of the present disclosure have developed a method for forming an electrode having a large sectional area by increasing thickness of the electrode more than by a general inkjet printing in such a manner that a buffer such as a wall is formed on the outside of an electrode pattern by inkjet printing and electrode ink is inkjet-printed inside the buffer as a new method of forming an electrode by the inkjet printing in which the electrode can be formed to have a precise pattern, which has limitation in increasing thickness of the electrode.

However, when the buffer formed to increase the sectional area of an electrode by limiting electrode ink inside the buffer does not have sufficient height, the sectional area of the electrode is not sufficiently increased despite the use of the buffer. In this case, when applying inkjet printing as the method of forming the buffer, ink used when forming the buffer may have characteristics different from the characteristics of electrode ink, but when applying inkjet printing, it is fundamentally difficult to form a buffer having sufficient height.

Accordingly, in consideration that composing a composition of ink which forms a buffer has lower limitation than composing a composition of electrode ink which is required to finally perform a function as an electrode, the inventors of the electrode forming apparatus have proposed the electrode forming apparatus by which the buffer is formed high through inkjet printing.

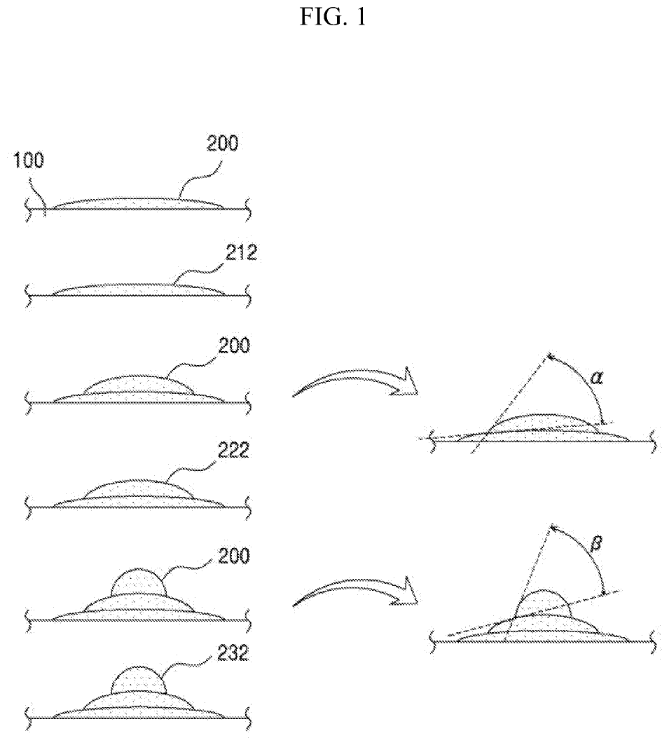

FIG. 1 is a sectional view illustrating a process of forming a buffer in the method for forming an electrode of an electronic device by using inkjet printing according to a first embodiment of the present disclosure.

As described above, the electrode forming method of the present disclosure is a method in which a buffer is formed by inkjet printing and electrode ink is filled inside the buffer by inkjet printing so as to increase a sectional area of an electrode. In this case, the sectional area of the electrode is determined according to the height of the buffer formed by inkjet printing, and thus it is the most important to make the buffer high. Hereinafter, the specific method of forming the buffer will be mainly described.

In the buffer forming method according to the embodiment of the present disclosure, first, a buffer ink 200 is ejected on the surface of an object 100, by inkjet printing, on which an electrode is required to be formed such that a pattern is formed. The pattern formed in this case corresponds to the outer edge of an electrode and is formed at an appropriate position to have an appropriate shape according to a desired shape of the electrode and characteristics of a buffer.

In this case, according to the surface condition of the object 100, whether the surface treatment of the object 100 is performed, and the type of ink, the ink ejected on the surface of the object may have a different surface contact angle. In order to make a buffer layer high, the buffer ink 200 is preferably printed to have a large contact angle to the surface of the object 100, but in some cases, the contact angle may be formed to be small. When the contact angle is formed to be small, it means that the height of the buffer ink 200 printed is low. A pattern can be precisely formed at a more correct position by inkjet printing than by a conventional screen printing, but the inkjet printing has a disadvantage in that the height of a printed pattern is low. However, there is no problem even if such a disadvantage of the inkjet printing is reproduced in the process of printing the buffer ink 200. Accordingly, when composing the buffer ink, it is unnecessary to adjust the ingredient of the ink to increase the viscosity and surface tension of the ink, and the pattern can be formed at a desired location to have a desired line width by inkjet printing.

As a pre-step for electrode formation, the buffer ink 200 printed goes through a drying process to form a first buffer layer 212. The first buffer layer 212 in which the buffer ink is dried preferably has hydrophilicity lower than hydrophilicity of the object 100. To this end, the ingredient of the buffer ink is adjusted such that the hydrophilicity thereof is lower than the hydrophilicity of the object 100 after the buffer ink is dried, and the first buffer layer 212 has preferably surface characteristics such that the surface contact angle of a buffer ink is 30 degrees or more when the buffer ink is ejected on the surface of the first buffer layer 212. The first buffer layer 212 is a component of a buffer to be formed after buffer ink is dried and buffer layers of the dried ink are stacked. The buffer may function only as a buffer regardless of an electrode through which electricity flows but in some cases, may function as a part of the electrode. When the buffer does not function as the electrode, the buffer ink may be provided by focusing on the characteristics of the buffer ink that is advantageous for performing inkjet printing without considering electrical characteristics and can be lowered in hydrophilicity after being dried. Even if the buffer functions as a part of an electrode, the area of the buffer is smaller than the total sectional area of the electrode and thus the buffer functions only a part of the entire function of the electrode through which electricity flows. Accordingly, the buffer ink is preferably provided by focusing on the characteristics of the buffer ink that is low in electrical characteristics but is advantageous for performing inkjet printing and can be lowered in hydrophilicity after being dried.

In this embodiment, the buffer ink 200 is inkjet-printed again on the surface of the first buffer layer 212 in which the buffer ink is dried. In this case, due to the surface characteristics of the first buffer layer 212, the contact angle of the buffer ink 200 to the first buffer layer 212 is larger compared to when the buffer ink 200 is printed on the object 100, and due to the angle of the surface of the first buffer layer 212, the contact angle of the buffer ink 200, which is printed on the surface of the first buffer layer 212, to the surface of the object 100 is further increased. In this case, to obtain this effect, the line width of the buffer ink 200 printed on the first buffer layer 212 is required to be smaller than the line width of the first buffer layer 212.

Accordingly, due to the surface characteristics of the first buffer layer 212, the buffer ink 200 printed at a large contact angle is dried to form a second buffer layer 222. For convenience of explanation in the drawing, the first buffer layer 212 and the second buffer layer 222 are illustrated by being separated by a boundary line, but since the same buffer ink is used, there may be no boundary line in an actual section.

As described above, due to the second buffer layer 222 formed due to the surface characteristics (the surface angle and low hydrophilicity) of the first buffer layer 212, the height of an electrode is higher than the height of an electrode formed when inkjet printing is repeatedly performed. Accordingly, when an electrode is formed by using a buffer in which the second buffer layer 222 is formed, the sectional area of the electrode can be larger than the sectional area of an electrode formed by a conventional technology.

However, in this embodiment, in order to further increase the sectional area of an electrode, a buffer layer is additionally formed. The buffer ink 200 is inkjet-printed again on the surface of the second buffer layer 222 formed at a large contact angle to the surface of the object 100. In this case, due to the surface characteristics of the second buffer layer 222, the contact angle of the buffer ink 200 to the second buffer layer 222 is larger compared to when the buffer ink is printed on the object 100, and due to the angle of the surface of the second buffer layer 222, the contact angle of the buffer ink 200, which is printed on the surface of the second buffer layer 222, to the surface of the object 100 is further increased. In this case, the line width of the buffer ink 200 printed on the second buffer layer 222 is required to be smaller than the line width of the second buffer layer 222.

Finally, the buffer ink 200 printed at a large contact angle due to the surface characteristics of the second buffer layer 222 is dried to form a third buffer layer 232. The third buffer layer 232 is formed at a large contact angle to the surface of each of the second buffer layer 222 and the object 100 and thus the final height of the third buffer layer 232 is very high.

Three buffer layers are formed in the illustrated embodiment, but according to the characteristics of a buffer ink, when the contact angle of the buffer ink is smaller, the number of the buffer layers may be more increased, and when the contact angle of the buffer ink is larger, two buffer layers may be formed. In this case, when the contact angle of a buffer layer, which is formed on a top layer, to the object surface is 60 degrees or more, a buffer having sufficient height can be formed, and thus the number of the buffer layers is preferably adjusted according to the height of the buffer.

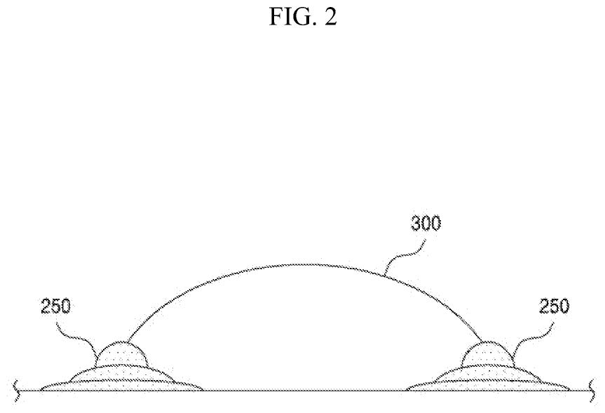

FIG. 2 is a view illustrating a section of an electrode formed in the method for forming an electrode of an electronic device by using inkjet printing according to the first embodiment of the present disclosure.

By inkjet printing, an electrode ink is filled inside a buffer 250 formed by stacking buffer inks by inkjet printing in the above-described process and is dried to form an electrode 300.

In this case, the height of the buffer 250 is high by being stacked up to the third buffer layer from the first buffer layer, and the electrode 300 formed by the electrode ink filled inside the buffer 250 has a sufficient sectional area.

Furthermore, since the printed electrode ink is in contact with the third buffer layer which is the top layer of the buffer 250, the electrode ink is not simply filled to be flat inside the buffer 250, but may be located by protruding convexly upward. Accordingly, since the third buffer layer formed with the buffer ink has low hydrophilicity like the first buffer layer and the second buffer layer, the contact angle of the electrode ink in contact with the third buffer layer may be formed to be large, and finally, the sectional area of the electrode 300 filled inside the buffer 250 can be further increased.

In addition, the buffer 250 may function only as a buffer regardless of the electrode 300 through which electricity flows, but in some cases, may function as a part of the electrode.

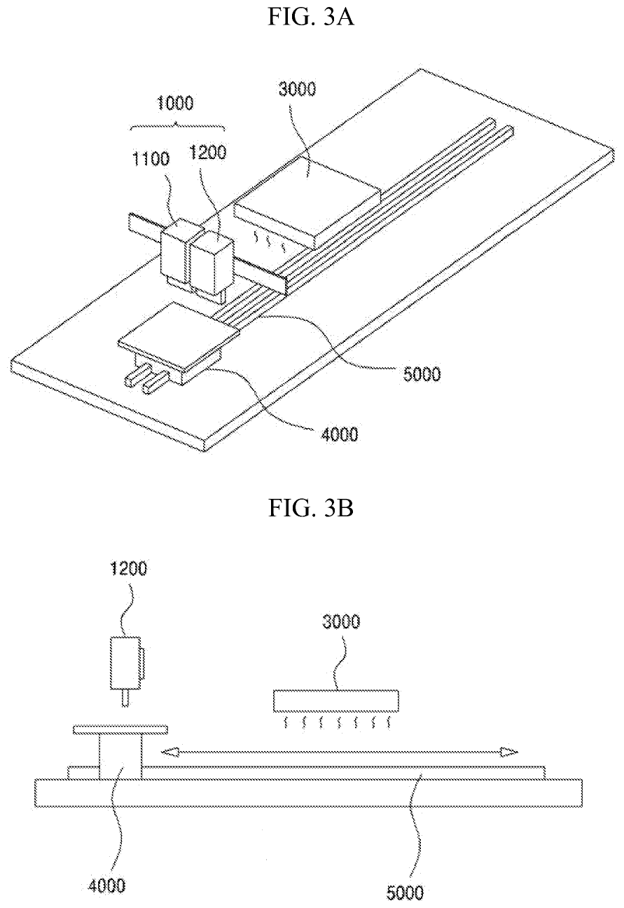

FIGS. 3A and 3B are views illustrating the structure of the electrode forming apparatus for forming an electrode in the first embodiment according to the method for forming an electrode of an electronic device by using inkjet printing according to the present disclosure.

The electrode forming apparatus for performing the electrode forming method according to the first embodiment described above includes a buffer ink discharge module 1100, an electrode ink discharge module 1200, a dryer 3000, a stage 4000, and a transportation means 5000.

The buffer ink discharge module 1100 is a component which ejects a buffer ink in an inkjet method for forming a buffer layer. A general technology of forming a part of an electronic device such as an electrode through inkjet printing may be applied thereto without limitation. Specifically, the buffer ink discharge module ‘1100 may be provided with an inkjet head for inkjet printing and may be provided with a transportation means for performing inkjet printing on a correct position. Various methods in which the relative positions of the inkjet head and an object can be changed may be applied to the transportation means. Although the inkjet head can be moved with the object fixed, the object is preferably moved. In addition, the buffer ink discharge module may include a storage part which stores ink inside the module, or may be configured to move only ink with the ink stored in a storage device provided separately outside the module. Furthermore, the buffer ink discharge module may be configured to unidirectionally move and supply ink toward the inkjet head, or may be configured in a circulation method of returning ink which is not ejected from the inkjet head. When the circulation method is applied, air bubbles that are introduced into ink are easily removed, and ink continuously moves and thus the uniformity of the ink can be improved. Particularly, when ink in which particles are dispersed is used, the dispersibility of the particles in the ink can be maintained.

The electrode ink discharge module 1200 is a component which ejects an electrode ink in an inkjet method for forming an electrode. A general technology of forming a part of an electronic device such as an electrode through inkjet printing may be applied thereto without limitation. Specifically, the electrode ink discharge module 1200 may be provided with an inkjet head for inkjet printing and may be provided with a transportation means for performing inkjet printing on a correct position. Various methods in which the relative positions of the inkjet head and an object can be changed may be applied to the transportation means. Although the inkjet head can be moved with the object fixed, the object is preferably moved. In addition, the electrode ink discharge module may include a storage part which stores ink inside the module, or may be configured to move only ink with the ink stored in a storage device provided separately outside the module. Furthermore, the electrode ink discharge module may be configured to unidirectionally move and supply ink toward the inkjet head, or may be configured in a circulation method of returning ink which is not ejected from the inkjet head. When the circulation method is applied, air bubbles that are introduced into ink are easily removed, and ink continuously moves and thus the uniformity of the ink can be improved. Particularly, when ink in which particles are dispersed is used, the dispersibility of the particles in the ink can be maintained.

The buffer ink discharge module 1100 and the electrode ink discharge module 1200 may be located separately but may perform functions thereof by using the same transportation means. That is, it is preferable to provide a printing part 1000 such that parts performing the same functions can be used together.

The dryer 3000 is a component which rapidly dries buffer ink and electrode ink printed on the surface of the object. According to the present disclosure, although inkjet printing is repeatedly performed, a next step is required to be performed after ink printed first is dried, and waiting for natural drying may delay an electrode forming process. Accordingly, when the dryer 3000 is separately installed and rapidly dries the printed ink, the speed of an entire electrode forming process is increased.

The stage 4000 is a component on which an object is installed such that a process such as inkjet printing is performed on the object. In the field of inkjet printing technology, various technologies of installing an object may be applied without limitation.

The transportation means 5000 is a component which allows an object to be located at the position of inkjet printing by the printing part 1000 and the position of ink drying by the dryer 3000. Remaining components may move with the stage fixed, but in this embodiment, by moving the stage 4000 on which the object is installed, the object is moved to a predetermined position of the printing part 1000 and a predetermined position of the dryer 3000.

When such an electrode forming apparatus is used, the formation of a buffer layer and the formation of an electrode are performed in the single apparatus without separate alignment, and thus the electrode forming process can be prevented from being delayed due to the repeated process of inkjet printing and the precision of the process can be increased.

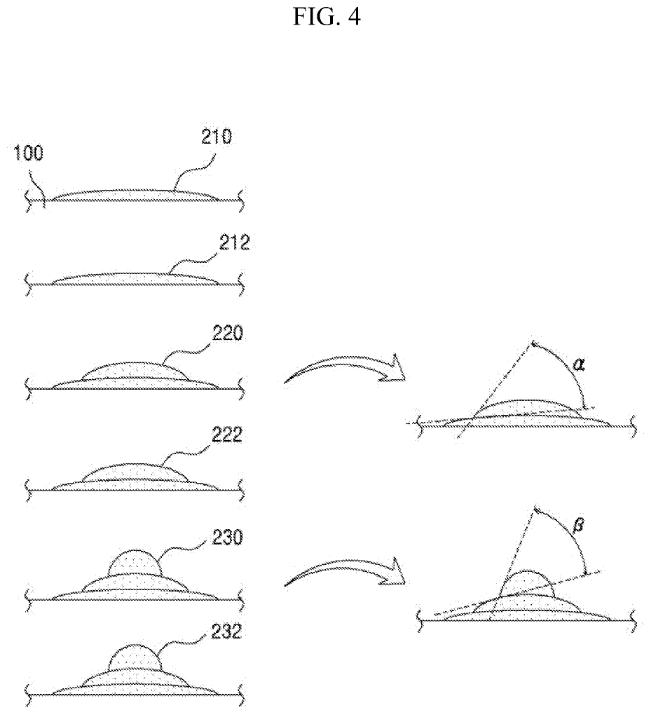

FIG. 4 is a sectional view illustrating the process of forming a buffer in the method for forming an electrode of an electronic device by using inkjet printing according to a second embodiment of the present disclosure.

As in the first embodiment, even in the electrode forming method according to the second embodiment, first, a first buffer ink 210 is ejected on the surface of the object 100 by inkjet printing on which an electrode is required to be formed such that a pattern is formed. The characteristics and patterned shape of the first buffer ink 210 are the same as the characteristics and patterned shape of the buffer ink of the first embodiment.

According to the surface condition of the object 100, whether the surface treatment of the object 100 is performed, and the type of ink, the first buffer ink 210 may be printed to have a small contact angle to the surface of the object 100, and this means that the height of the first buffer ink 210 printed is low. In inkjet printing, a pattern can be formed precisely in an accurate position compared to conventional screen printing, but there is a disadvantage that the height of a printed pattern is decreased. However, there is no problem even if such a disadvantage of inkjet printing is reproduced in the process of printing the first buffer ink 210. Accordingly, when composing the first buffer ink, it is unnecessary to adjust the ingredient of the ink to increase the viscosity and surface tension of the ink, and the pattern can be formed at a desired location to have a desired line width by inkjet printing.

The second embodiment is different from the first embodiment in that a plurality of buffer inks having different ingredients are used in the second embodiment unlike the method in which the same type of buffer ink is repeatedly used in the first embodiment described above.

In the second embodiment, a second buffer ink 220 having an ingredient different from the ingredient of the first buffer ink 210 is inkjet-printed on the surface of the first buffer layer 212 in which the first buffer ink 210 is dried. Although the second buffer ink 220 is different in ingredients from the first buffer ink 210, due to the surface characteristics of the first buffer layer 212, the contact angle of the second buffer ink 220, which is printed on the surface of the first buffer layer 212, to the surface of the object 100 is further increased. In this case, the line width of the second buffer ink 220 printed on the first buffer layer 212 is preferably smaller than the line width of the first buffer layer 212. The ingredient of the second buffer ink is not particularly limited but should not dissolve the previously printed first buffer layer. The ingredient of the second buffer ink is applied to compensate for the shortcomings of the first buffer ink to eliminate the limitation of the ingredient used in the first buffer ink. For example, when ink is good in the characteristics of an contact angle but has an ingredient or composition with low adhesion to an object, this ink is difficult to be used as the first buffer ink, and thus ink having an ingredient or composition with high adhesion to the object is used as the first buffer ink, so finally, the problem of adhesion to the object can be solved. For another example, when ink is good in the characteristics of an contact angle but has an ingredient or composition excessively bad in electrical characteristics such that the ink has a negative effect on a final electrode, this ink is used as the first buffer ink to increase the contact angle of the ink to the surface of the object, and ink of an ingredient or composition which can reduce the problem of the first buffer layer is used as the second buffer ink to solve the problem of the decrease of the electrical characteristics of the final electrode. In addition, when using the second buffer ink which can compensate for the shortcomings of the first buffer ink, the process of composing the first buffer ink is easy and finally, the characteristics of the electrode are not deteriorated.

Accordingly, due to the surface characteristics of the first buffer layer 212, the second buffer ink 220 printed at a large contact angle is dried to form the second buffer layer 222.

In addition, when a third buffer ink 230 is inkjet-printed on the surface of the second buffer layer 222 formed at a large contact angle to the surface of the object 100, as in the first embodiment, the contact angle of the third buffer ink 230, which is printed on the surface of the second buffer layer 222, to the surface of the object 100 is further increased. In this case, the line width of the third buffer ink 230 printed on the second buffer layer 222 is preferably smaller than the line width of the second buffer layer 222. The third buffer ink may have the same ingredient as the ingredient of the first buffer ink or the second buffer ink, or may have an ingredient different from the ingredient of the first buffer ink or the second buffer ink. In this case, the third buffer ink is characteristically required not to dissolve the first buffer ink or the second buffer ink. When the third buffer ink has an ingredient different from the ingredient of each of the first buffer ink and the second buffer ink, as previously described about the second buffer ink, the third buffer ink is preferably provided to have characteristics compensating for the shortcomings of the first buffer ink and the second buffer ink. Additionally, a portion of the first to third buffer layers may have ink provided to function as an electrode, and when the third buffer layer in contact with an electrode ink is provided to be close to the characteristics of the electrode, a sectional area of the electrode which functions as an electrode may be further increased.

Finally, due to the surface characteristics of the second buffer layer 222, the buffer ink 200 printed at a large contact angle is dried to form the third buffer layer 232. The third buffer layer 232 is formed at a large contact angle to the surface of each of the second buffer layer 222 and the object 100, and the height of the printed third buffer layer is high, and thus more electrode ink may be filled inside the buffer layers.

Forming an electrode by using a buffer formed by stacking three buffer layers in the above-described method is similar to the case of FIG. 2 and thus a detailed description thereof will be omitted.

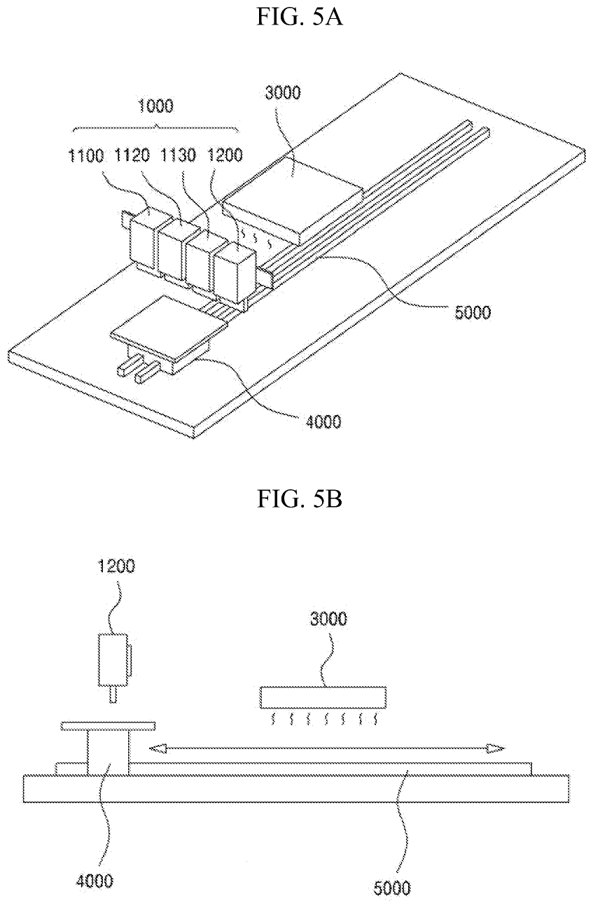

FIGS. 5A and 5B are views illustrating the structure of the electrode forming apparatus for forming an electrode in the second embodiment according to the method for forming an electrode of an electronic device by using inkjet printing according to the present disclosure.

The electrode forming apparatus for performing the electrode forming method according to the second embodiment described above includes a first buffer ink discharge module 1110, a second buffer ink discharge module 1120, a third buffer ink discharge module 1130, the electrode ink discharge module 1200, the dryer 3000, the stage 4000, and the transportation means 5000.

In the electrode forming method according to the second embodiment, an electrode forming apparatus used when three types of buffer inks are used includes three buffer ink modules. When using two types of buffer inks, the electrode forming apparatus may include two buffer ink modules.

The first buffer ink discharge module 1110, the second buffer ink discharge module 1120, and the third buffer ink discharge module 1130 are which respectively eject the first buffer ink, the second buffer ink, and the third buffer ink in an inkjet method for forming the first buffer layer, the second buffer layer, and the third buffer layer. A general technology of forming a part of an electronic device such as an electrode through inkjet printing may be applied thereto without limitation. Specifically, each of the buffer ink discharge modules may be provided with an inkjet head for inkjet printing and may be provided with a transportation means for performing inkjet printing on a correct position. Various methods in which the relative positions of the inkjet head and an object can be changed may be applied to the transportation means. Although the inkjet head can be moved with the object fixed, the object is preferably moved. In addition, the electrode ink discharge module may include a storage part which stores ink inside the module, or may be configured to move only ink with the ink stored in a storage device provided separately outside the module. Furthermore, the electrode ink discharge module may be configured to unidirectionally move and supply ink toward the inkjet head, or may be configured in a circulation method of returning ink which is not ejected from the inkjet head. When the circulation method is applied, air bubbles that are introduced into ink are easily removed, and ink continuously moves and thus the uniformity of the ink can be improved. Particularly, when ink in which particles are dispersed is used, the dispersibility of the particles in the ink can be maintained.

The electrode ink discharge module 1200 is a component which ejects an electrode ink in an inkjet method for forming an electrode. A general technology of forming a part of an electronic device such as an electrode through inkjet printing may be applied thereto without limitation. Specifically, electrode ink discharge module 1200 may be provided with an inkjet head for inkjet printing and may be provided with a transportation means for performing inkjet printing on a correct position. Various methods in which the relative positions of the inkjet head and an object can be changed may be applied to the transportation means. Although the inkjet head can be moved with the object fixed, the object is preferably moved. In addition, the electrode ink discharge module may include a storage part which stores ink inside the module, or may be configured to move only ink with the ink stored in a storage device provided separately outside the module. Furthermore, the electrode ink discharge module may be configured to unidirectionally move and supply ink toward the inkjet head, or may be configured in a circulation method of returning ink which is not ejected from the inkjet head. When the circulation method is applied, air bubbles that are introduced into ink are easily removed, and ink continuously moves and thus the uniformity of the ink can be improved. Particularly, when ink in which particles are dispersed is used, the dispersibility of the particles in the ink can be maintained.

The first to third buffer ink discharge modules 1110, 1120, and 1130 and the electrode ink discharge module 1200 may be located separately but may perform functions thereof by using the same transportation means. That is, it is preferable to provide the printing part 1000 such that parts performing the same functions can be used together.

The dryer 3000 is a component which rapidly dries buffer ink and electrode ink printed on the surface of the object. According to the present disclosure, although inkjet printing is repeatedly performed, a next step is required to be performed after ink printed first is dried, and waiting for natural drying may delay the electrode forming process. Accordingly, when the dryer 3000 is separately installed and rapidly dries the printed ink, the speed of an entire electrode forming process is increased.

The stage 4000 is a component on which an object is installed such that a process such as inkjet printing is performed on the object. In the field of inkjet printing technology, various technologies of installing an object may be applied without limitation.

The transportation means 5000 is a component which allows an object to be located at the position of inkjet printing by the printing part 1000 and the position of ink drying by the dryer 3000. Remaining components may move with the stage fixed, but in this embodiment, by moving the stage 4000 on which the object is installed, the object is moved to a predetermined position of the printing part 1000 and a predetermined position of the dryer 3000.

When such an electrode forming apparatus is used, the formation of the buffer layer and the formation of an electrode are performed in a single apparatus without separate alignment, and thus the electrode forming process can be prevented from being delayed due to the repeated process of inkjet printing and the precision of the process can be increased.

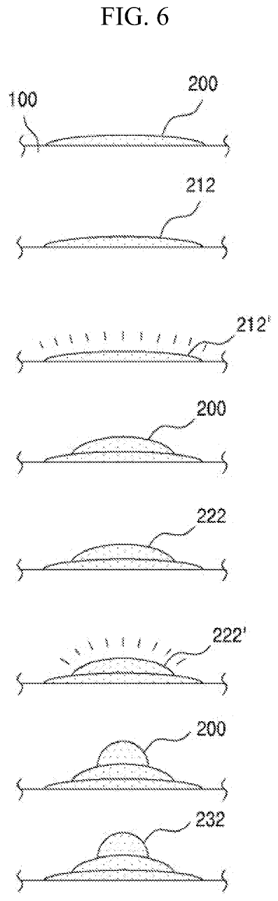

FIG. 6 is a sectional view illustrating the method for forming an electrode of an electronic device by using inkjet printing according to a third embodiment of the present disclosure.

Hereinafter, differences of the third embodiment from the first embodiment will be mainly described.

Even in the electrode forming method of this embodiment, first, the buffer ink 200 is ejected on the surface of the object 100, by inkjet printing, on which an electrode is required to be formed, as in the first embodiment, such that a pattern is formed.

In addition, the printed buffer ink 200 goes through a drying process to form the first buffer layer 212, and the surface of the first buffer layer 212 is treated. In the previous embodiments is used the buffer ink prepared such that the hydrophilicity of the surface of the first buffer layer is decreased more than the hydrophilicity of the object 100 only by drying the buffer ink.

However, the buffer ink showing these properties has limited ingredient and composition, and in this embodiment, in order to increase the ingredient and composition of the buffer ink, a hydrophobic surface treatment is performed on a dried surface to reduce the hydrophilicity of the surface compared to the object 100. To this end, the ingredient of the buffer ink are adjusted such that the hydrophilicity of the surface thereof is lower than the hydrophilicity of the surface of the object 100 through the surface treatment after the buffer ink is dried, and the surface-treated first buffer layer 212 has lower hydrophilicity than the object 100. The first buffer layer 212 is a component of a buffer to be formed in such a manner that the buffer ink is dried and buffer layers of the dried ink are stacked, and the buffer may function only as a buffer regardless of an electrode through which electricity flows, but in some cases, may function as a part of the electrode. When the buffer does not function as the electrode, the buffer ink may be provided by focusing on the characteristics of the buffer ink that is advantageous for performing inkjet printing without considering electrical characteristics and can be lowered in hydrophilicity by surface treatment. Even if the buffer functions as a part of an electrode, the buffer has an area smaller than the total sectional area of the electrode and performs only a small portion of the entire function of the electrode through which electricity flows. Accordingly, even if the buffer ink has a slightly low electrical characteristic, the buffer ink is preferably provided by focusing on the characteristics of the buffer ink that is advantageous for inkjet printing and can be lowered in hydrophilicity by surface treatment. Furthermore, the surface treatment performed on the surface of the buffer layer is not particularly limited, and various techniques capable of lowering the hydrophilicity of the surface may be applied. In this case, it is possible to prevent damage to an object or other parts by applying a technique that can perform surface treatment only on the surface of the buffer layer or a surface treatment technique that acts only on the buffer layer without acting on an object or other parts.

In addition, as in the first embodiment, the method of repeatedly forming a buffer layer is applied, and the same type of buffer ink is repeatedly used.

In this embodiment, the buffer ink 200 is inkjet-printed again on the surface of the surface-treated first buffer layer 212, and the buffer ink 200 printed on the surface of the first buffer layer 212 has a more increased contact angle to the surface of the object 100. In this case, the line width of the buffer ink 200 printed on the surface-treated first buffer layer 212 is preferably smaller than the line width of the first buffer layer 212.

Accordingly, due to the surface characteristics of the first buffer layer 212, the buffer ink 200 printed to have a large contact angle is dried to form the second buffer layer 222, and the surface of the second buffer layer 222 is treated. For convenience of explanation in the drawing, the first buffer layer 212 and the second buffer layer 222 are illustrated by being separated by a boundary line, but since the same buffer ink is used, there may be no boundary line in an actual section despite the surface treatment.

In addition, as described above, a buffer formed by stacking two buffer layers may be used, but as in the first embodiment, the third buffer layer is additionally formed.

The buffer ink 200 is inkjet-printed on the surface of the second buffer layer 222 formed to have a large contact angle to the surface of the object 100 and is dried to form the third buffer layer 232. The third buffer layer 232 is formed to have a large contact angle to the surface of each of the second buffer layer 222 and the object 100, and thus the final height of the third buffer layer 232 is very high. When the electrode ink is filled inside a buffer constituted by the first to third buffer layers, an electrode having a large sectional area can be formed.

In the illustrated embodiment, three buffer layers are formed, but when a contact angle is lower according to the characteristics of the buffer ink, the number of buffer layers may be increased, and when a contact angle is larger, two buffer layers may be formed.

Forming an electrode by using a buffer in which three buffer layers are stacked in the above method is similar to the case of FIG. 2 and thus a detailed description thereof will be omitted.

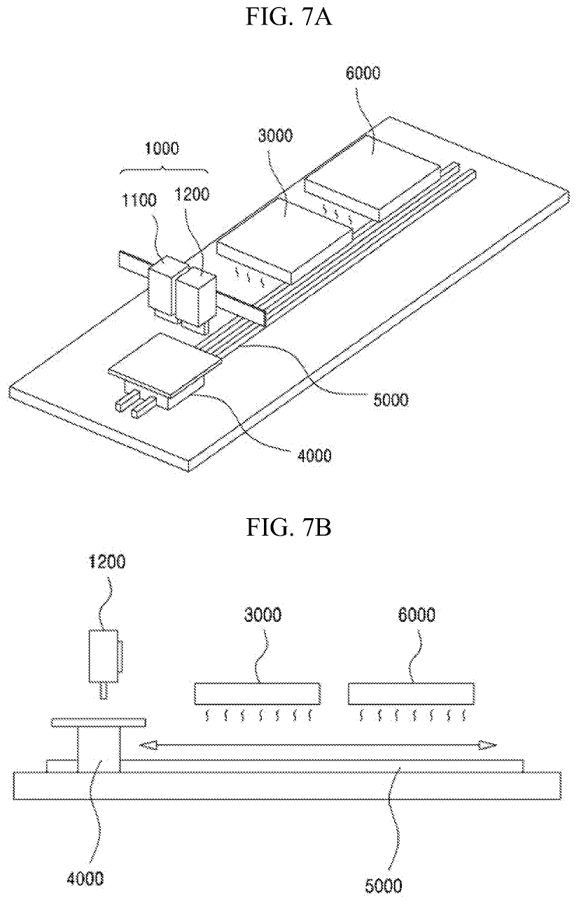

FIGS. 7A and 7B are views illustrating the structure of the electrode forming apparatus for forming an electrode in the third embodiment according to the method for forming an electrode of an electronic device by using inkjet printing according to the present disclosure.

The electrode forming apparatus for performing the electrode forming method according to the third embodiment described above includes the buffer ink discharge module 1100, the electrode ink discharge module 1200, the dryer 3000, a surface treatment device 6000, the stage 4000, and the transportation means 5000.

Except for the addition of the surface treatment device 6000 to the electrode forming apparatus of this embodiment, the electrode forming apparatus of this embodiment has the same configuration as the electrode forming apparatus of FIGS. 3A and 3B and thus a detailed description thereof will be omitted.

The surface treatment device 6000 is a component for reducing hydrophilicity of a surface of a buffer layer by treating the surface of the buffer layer in which buffer ink is dried. Since there is no particular limitation in a surface treatment technology, the surface treatment device is not limited, and various technologies and surface treatment devices that can lower the hydrophilicity of the surface may be applied. In this case, it is possible to prevent damage to an object or other parts by applying a technique that can perform surface treatment only on the surface of the buffer layer or a surface treatment technique that acts only on the buffer layer without acting on an object or other parts.

When such an electrode forming apparatus is used, the formation of the buffer layer, surface treatment thereof, and the formation of an electrode are performed in a single apparatus without separate alignment, and thus the electrode forming process can be prevented from being delayed due to the repeated process of inkjet printing and the precision of the process can be increased.

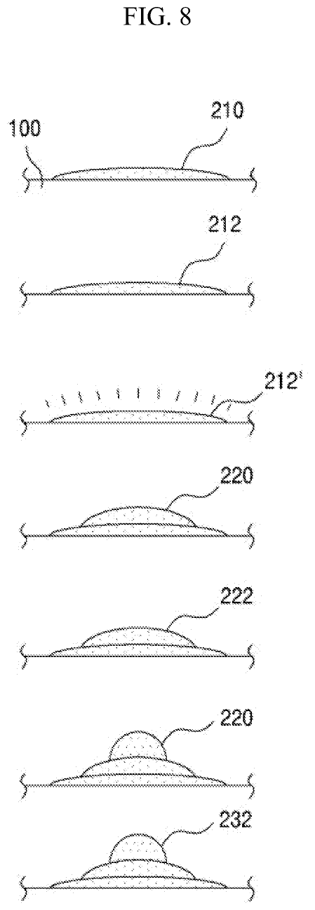

FIG. 8 is a sectional view illustrating the method for forming an electrode of an electronic device by using inkjet printing according to a fourth embodiment of the present disclosure.

The electrode forming method of the fourth embodiment is similar to the electrode forming method of the second embodiment in that other types of buffer inks are used. The fourth embodiment is similar to the third embodiment in that the surface of at least one buffer ink is treated to lower hydrophilicity thereof.

Specifically, the first buffer layer 212, the second buffer layer 222, and the third buffer layer 232 are formed by using the first buffer ink 210 and the second buffer ink 220. In this case, the first buffer ink 210 which can lower hydrophilicity of the dried surface of the first buffer layer 212 more than hydrophilicity of the object 100 by performing surface treatment on the dried surface of the first buffer layer 212 in the process of forming the first buffer layer 212 is used and is dried and then the surface of the first buffer ink 210 is treated. The first buffer layer 212 in which the first buffer ink is dried may function only as a buffer regardless of an electrode through which electricity flows, but in some cases, may function as a part of the electrode. When the first buffer layer 212 does not function as the electrode, the buffer ink may be provided by focusing on the characteristics of the buffer ink that is advantageous for performing inkjet printing without considering electrical characteristics and can be lowered in hydrophilicity by surface treatment. Even if the first buffer layer 212 functions as a part of an electrode, the buffer has an area smaller than the total sectional area of the electrode and performs only a small portion of the entire function of the electrode through which electricity flows. Accordingly, even if the first buffer ink has a slightly low electrical characteristic, the first buffer ink is preferably provided by focusing on the characteristics of the first buffer ink that is advantageous for inkjet printing and can be lowered in hydrophilicity by surface treatment. Furthermore, the surface treatment performed on the surface of the first buffer layer 212 is not particularly limited, and various techniques capable of lowering the hydrophilicity of the surface may be applied. In this case, it is possible to prevent damage to an object or other parts by applying a technique that can perform surface treatment only on the surface of the first buffer layer or a surface treatment technique that acts only on the first buffer layer without acting on an object or other parts.

The second buffer ink 220 is printed on the surface-treated first buffer layer 212 and is dried to form the second buffer layer 222. Unlike the first buffer ink, the second buffer ink of this embodiment is dried and hydrophilicity of the surface thereof is lower than hydrophilicity of the object, and accordingly, separate surface treatment is not performed.

Except for the characteristic of hydrophilicity, the ingredient of the second buffer ink is not particularly limited but is required not to dissolve the first buffer layer printed previously. The second buffer ink is applied to compensate for the shortcomings of the first buffer ink to eliminate the limitation of the ingredient used in the first buffer ink.

In addition, the second buffer ink 220 is additionally inkjet-printed on the surface of the second buffer layer 222 formed to have a large contact angle to the surface of the object 100 and is dried to form the third buffer layer 232. The third buffer layer 232 is formed to have a large contact angle to the surface of each of the second buffer layer 222 and the object 100, and thus the final height of the third buffer layer 232 is very high. When the electrode ink is filled inside a buffer constituted by the first to third buffer layers, an electrode having a large sectional area can be formed.

Forming an electrode by using a buffer formed by stacking three buffer layers in the above-described method is similar to the case of FIG. 2 and thus a detailed description thereof will be omitted.

Furthermore, it is not restrictive that the first buffer ink requires surface treatment and the second buffer ink does not require surface treatment. The first buffer ink may not require surface treatment and the second buffer ink may require surface treatment, or even if the first buffer ink and the second buffer ink have different ingredients, both the first buffer ink and the second buffer ink may require surface treatment.

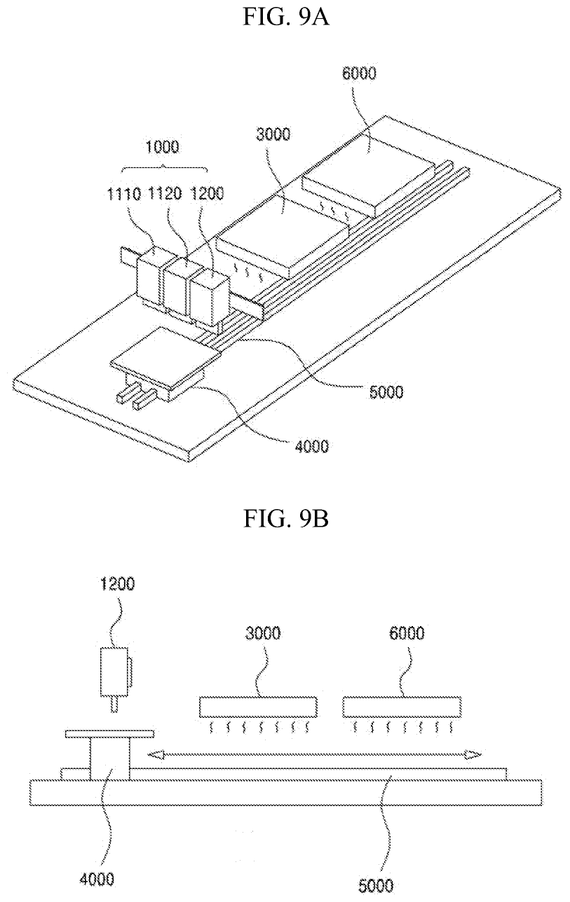

FIGS. 9A and 9B are views illustrating the structure of the electrode forming apparatus for forming an electrode in the fourth embodiment according to the method for forming an electrode of an electronic device by using inkjet printing according to the present disclosure.

The electrode forming apparatus for performing the electrode forming method according to the fourth embodiment described above includes the first buffer ink discharge module 1110, the second buffer ink discharge module 1120, the electrode ink discharge module 1200, the dryer 3000, the surface treatment device 6000, the stage 4000, and the transportation means 5000.

Since two types of buffer inks are used, the first buffer ink discharge module 1110 and the second buffer ink discharge module 1120 are all provided, and remaining components may be the same as the components of the electrode forming apparatus described above.

When such an electrode forming apparatus is used, the formation of the buffer layer and the formation of an electrode are performed in a single apparatus without separate alignment, and thus the electrode forming process can be prevented from being delayed due to the repeated process of inkjet printing and the precision of the process can be increased.

The present disclosure has been described above through the exemplary embodiments, but the above-described embodiments are merely illustrative of the technical spirit of the present disclosure, and those skilled in the art will understand that various changes are possible within the scope of the present disclosure without departing from the technical spirit of the present disclosure. Accordingly, the protection scope of the present disclosure should be interpreted by matters described in the claims, not specific embodiments, and all technical ideas within the equivalent range should be construed as being included in the scope of the present disclosure.

What is claimed is:

1. A method of forming an electrode on a surface of an object by using inkjet printing, the method comprising:
forming a buffer on an outer edge of an electrode formation position; and
forming the electrode by filling electrode ink inside the buffer,
wherein the buffer formation is performed in such a manner that a process of forming a buffer layer by inkjet printing of buffer ink is repeated to stack buffer layers, and
hydrophilicity of a surface of the buffer layer is lower than hydrophilicity of the object surface.

2. The method of claim 1, wherein the buffer formation is performed in such a manner that a process of forming a buffer layer by inkjet printing of each of at least two types of buffer inks having different ingredients is repeated to stack buffer layers.

3. The method of claim 1, wherein the buffer formation comprises a process of performing surface treatment of the buffer layer,
wherein the surface treatment allows the hydrophilicity of the buffer layer surface to be lower than the hydrophilicity of the object surface.

4. The method of claim 1, wherein the buffer formation is performed by stacking the buffer layer at least two times to form a plurality of buffer layers, wherein a surface of at least one of the plurality of buffer layers is treated to have hydrophilicity lower than the hydrophilicity of the object surface.

5. An apparatus for forming an electrode on a surface of an object by using inkjet printing, the apparatus comprising:
a buffer ink discharge module for inkjet printing of buffer ink which forms a buffer layer whose surface has hydrophilicity lower than hydrophilicity of the object surface;
an electrode ink discharge module for inkjet printing of electrode ink inside a buffer whose buffer layers are stacked;
a dryer for drying inkjet-printed ink;
a stage for mounting the object on which the electrode is formed; and
a transportation means which moves a position of the object, which is installed on the stage, relative to the buffer ink discharge module, the electrode ink discharge module, and the dryer.

6. The apparatus of claim 5, wherein the buffer ink discharge module comprises at least two buffer ink discharge modules to eject buffer inks different from each other.

7. The apparatus of claim 5, further comprising:
a surface treatment device which treats a surface of a buffer layer in which buffer ink is dried such that hydrophilicity of the surface of the buffer layer is lower than the hydrophilicity of the object surface.
